(19) United States
(12) Patent Application Publication
(10) Pub. No.: US 2011/0128426 A1
(43) Pub. Date: Jun. 2, 2011

(54) SOLID-STATE IMAGING APPARATUS

(75) Inventors: Hisayuki Taruki, Kanagawa (JP); Nagataka Tanaka, Kanagawa (JP)

(73) Assignee: Kabushiki Kaisha Toshiba, Tokyo (JP)

(21) Appl. No.: 12/885,965

(22) Filed: Sep. 20, 2010

(30) Foreign Application Priority Data
Nov. 30, 2009 (JP) 2009-272369

(51) Int. Cl. H04N 5/335

(52) U.S. Cl. 348/300; 348/302; 348/E05.091

(57) ABSTRACT

A solid-state imaging apparatus according to an embodiment includes pixels, horizontal control lines, vertical signal lines, a vertical scan circuit and a signal processing circuit; the horizontal control lines selecting the pixels in the row direction, the vertical signal lines having n lines (n is integer of 2 or larger) thereof arranged for each column so as to mutually intersect and being connected separately to pixels divided into n groups for each column, the vertical scan circuit selecting the horizontal control lines, and signal processing circuit processing pixel signals read out via the vertical signal lines simultaneously.

### CROSS-REFERENCE TO RELATED APPLICATIONS

This application is based upon and claims the benefit of priority from the prior Japanese Patent Application No. 2009-272369, filed on Nov. 30, 2009; the entire contents of which are incorporated herein by reference.

### FIELD

The present embodiment generally relates to a solid-state imaging apparatus.

### BACKGROUND

It has been desired to shorten time required for image processing such as A/D conversion in accordance with enhancing of frame rate, increase of pixel number and increase of output bit number. In order to meet such requirement, a method to divide a pixel area into two and to simultaneously read out a signal of one row from the respective two pixel areas has been disclosed in Japanese Patent Application Laid-Open No. 2007-116479.

However, with the method disclosed in Japanese Patent Application Laid-Open No. 2007-116479, vertical signal lines are required to be separated at the boundary portion between the pixel areas. Accordingly, there has been a problem that layout at the boundary portion between the pixel areas is different from that of a circumferential portion to cause different pixel characteristics due to difference of wiring capacitance and to cause affection to optical characteristics.

Further, although output circuits may be arranged above and below when dividing the pixel area into two, there has been a problem that output circuits are difficult to be placed outside the pixel area when dividing the pixel area into three or more.

### BRIEF DESCRIPTION OF THE DRAWINGS

FIG. 1 is a block diagram which illustrates a general configuration of a solid-state imaging apparatus according to a first embodiment of the invention;

FIG. 2 is an equivalent circuit diagram which illustrates a general configuration of two pixels being mutually adjacent in the column direction of FIG. 1;

FIG. 3 is a plane view which illustrates a layout configuration of the two pixels being mutually adjacent in the column direction of FIG. 1; and

FIG. 4 is a plane view which illustrates a layout configuration of three pixels being mutually adjacent in the column direction of a solid-state imaging apparatus according to a second embodiment of the invention.

### DETAILED DESCRIPTION

A solid-state imaging apparatus according to an embodiment is provided with pixels, horizontal control lines, vertical signal lines, a vertical scan circuit and a signal processing circuit. The pixels are arrayed in a matrix shape in the row direction and the column direction. The horizontal control lines select the pixels in the row direction. The vertical signal lines are arranged as n lines (n is integer of 2 or larger) for each column so as to mutually intersect and are connected separately to pixels divided into n groups for each column. The vertical scan circuit selects the horizontal control lines. The signal processing circuit processes pixel signals read out via the vertical signal lines.

In the following, solid-state imaging apparatuses according to embodiments of the invention will be described with reference to the drawings. The present invention is not limited to the following embodiments.

### First Embodiment

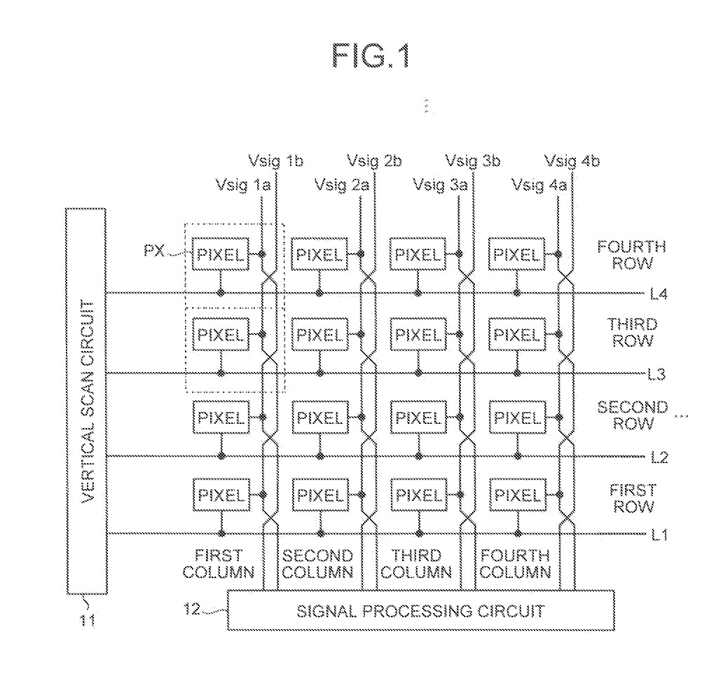

FIG. 1 is a block diagram illustrating a general configuration of a solid-state imaging apparatus according to the first embodiment of the invention.

In FIG. 1, pixels PX are arrayed at the solid-state imaging apparatus being a matrix shape in the row direction and the column direction. Then, the solid-state imaging apparatus is provided with horizontal control lines L1 to L4 to select pixels PX in the row direction and vertical signal lines Vsig1a to Vsig4a and Vsig1b to Vsig4b to transmit pixel signals read from the pixels PX to the column direction. Here, for example, the horizontal control lines L1 to L4 can include read lines to read from the pixels PX, reset lines to reset electric charge accumulated at the pixels PX and address lines to perform column selection for reading.

Only two lines among the vertical signal lines Vsig1a to Vsig4a and Vsig1b to Vsig4b are arranged for each column. For example, vertical signal lines Vsig1a, Vsig1b are arranged on the first column. Vertical signal lines Vsig2a, Vsig2b are arranged on the second column. Vertical signal lines Vsig3a, Vsig3b are arranged on the third column. Then, vertical signal lines Vsig4a, Vsig4b are arranged on the fourth column.

The vertical signal lines Vsig1a, Vsig1b are arranged as mutually intersecting for every pixel in the column direction. The vertical signal lines Vsig2a, Vsig2b are arranged as mutually intersecting for every pixel in the column direction. The vertical signal lines Vsig3a, Vsig3b are arranged as mutually intersecting for every pixel in the column direction. Then, the vertical signal lines Vsig4a, Vsig4b are arranged as mutually intersecting for every pixel in the column direction. Further, the pixels PX are arrayed so as to be aligned for each column in the column direction.

Further, the solid-state imaging apparatus is provided with a vertical scan circuit 11 to select the horizontal control lines L1 to L4 and a signal processing circuit 12 to process pixel signals read via the vertical signal lines Vsig1a to Vsig4a and Vsig1b to Vsig4b.

Here, the vertical scan circuit 11 can select the horizontal control lines L1 to L4 so that pixel signals are simultaneously read out to two vertical signal lines Vsig1a to Vsig4a and Vsig1b to Vsig4b of each column from two mutually adjacent pixels PX. In the case that a signal is read out to the vertical signal line Vsig1b from a pixel PX on the first column and a signal is read out to the vertical signal line Vsig1a from a pixel PX on the second column, the vertical scan circuit 11 simultaneously selects the horizontal control lines L1, L2, so that the signals can be transmitted to the signal processing circuit 12.

The signal processing circuit 12 can simultaneously process pixel signals read out from two mutually adjacent pixels PX respectively via two vertical signal lines Vsig1a to Vsig4a and Vsig1b to Vsig4b. For example, the pixel signals simultaneously transmitted via the vertical signal lines Vsig1a, Vsig1b can be simultaneously processes.

Here, by arranging the vertical signal lines Vsig1a to Vsig4a and Vsig1b to Vsig4b being mutually intersecting for every pixel in the column direction, the pixels PX can be arrayed so as to be aligned in position in the column direction for each column. Therefore, even in the case that mutually adjacent pixels PX on the same column are connected respectively to mutually different vertical signal lines Vsig1a to Vsig4a and Vsig1b to Vsig4b, pixel characteristics and optical characteristics can be evened. Accordingly, reading speed of one frame quantity from the pixels PX can be increased while suppressing deterioration of image quality.

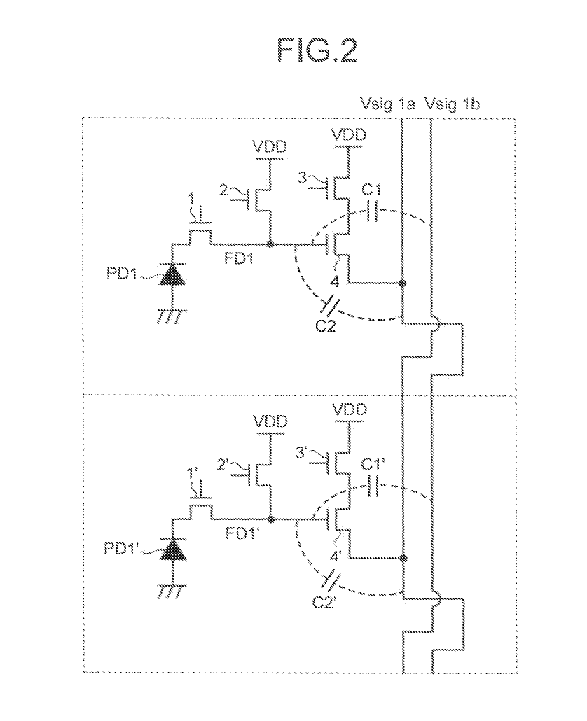

FIG. 2 is an equivalent circuit diagram illustrating a general configuration of two pixels being mutually adjacent in the column direction of FIG. 1 (i.e., the dotted line frame part in FIG. 1).

As illustrated in FIG. 2, the two pixels PX being mutually adjacent in the column direction is respectively provided with a read transistor 1, 1′, a reset transistor 2, 2′, an address transistor 3, 3′, an amplifier transistor 4, 4′, a photodiode PD1, PD1′ and a floating diffusion FD1, FD1′. Here, a parasitic capacitance C1 is added between the floating diffusion FD1 and the vertical signal line Vsig1b and a parasitic capacitance C2 is added between the floating diffusion FD1 and the vertical signal line Vsig1a. Further, a parasitic capacitance C1′ is added between the floating diffusion FD1′ and the vertical signal line Vsig1a and a parasitic capacitance C2′ is added between the floating diffusion FD1′ and the vertical signal line Vsig1b.

Then, sources of the read transistors 1, 1′ are respectively connected to the photodiodes PD1, PD1′. Gates of the read transistors 1, 1′ are respectively connected to read lines. Further, sources of the reset transistors 2, 2′ are respectively connected to drains of the read transistors 1, 1′. Gates of the reset transistors 2, 2′ are respectively connected to reset lines. Drains of the reset transistors 2, 2′ are connected to power source potential VDD. Further, gates of the address transistors 3, 3′ are respectively connected to address lines. Drains of the address transistors 3, 3′ are connected to the power source potential VDD. Further, sources of the amplifier transistors 4, 4′ are respectively connected to the vertical signal lines Vsig1a, Vsig1b. Gates of the amplifier transistors 4, 4′ are respectively connected to the drains of the read transistors 1, 1′. Drains of the amplifier transistors 4, 4′ are respectively connected to the sources of the address transistors 3, 3′.

Here, the floating diffusions FD1, FD1′ are respectively formed at connection points of the gates of the amplifier transistors 4, 4′ and the drains of the read transistors 1, 1′.

When the address lines of the horizontal control lines L3, L4 of FIG. 1 are low level, the address transistors 3, 3′ are turned off and source follower operation is not performed thereby. Accordingly, a signal is not output. In this state, when the read lines of the horizontal control lines L3, L4 become high level, the read transistors 1, 1′ of the pixels on the third and fourth rows are turned on. Then, signal charges accumulated at the photodiode PD1, PD1′ are transmitted respectively to the floating diffusions FD1, FD1′. Subsequently, accumulation of effective signal charges is started at the photodiodes PD1, PD1′. When the reset lines of the horizontal control lines L3, L4 become high level after the signal charges are read out to the floating diffusions FD1, FD1′, the reset transistors 2, 2′ are turned on. Accordingly, the signal charges read out to the floating diffusions FD1, FD1′ are discharged.

Next, when the address lines of the horizontal control lines L3, L4 become high level, the address transistors 3, 3′ are turned on and the source follower is constituted with the amplifier transistors 4, 4′ and load transistors. Accordingly, signals can be output. When the reset lines of the horizontal control lines L3, L4 become high level, the reset transistors 2, 2′ are turned on and charges accumulated at the floating diffusions FD1, FD1′ are reset. At that time, reset voltages of the floating diffusions FD1, FD1′ are output respectively via the vertical signal lines Vsig1a, Vsig1b. Then, the reset voltages are maintained at the signal processing circuit 12.

Next, when the read lines of the horizontal control lines L3, L4 become high level in the state that the address transistors 3, 3′ are ON, the read transistors 1, 1′ are turned on. Accordingly, signal charge amounts accumulated at the photodiodes PD1, PD1′ are read out to the floating diffusions FD1, FD1′. Signal voltages (i.e., the reset voltage+the signal voltage) varied at the floating diffusions FD1, FD1′ are output to the signal processing circuit 12 respectively via the vertical signal lines Vsig1a, Vsig1b.

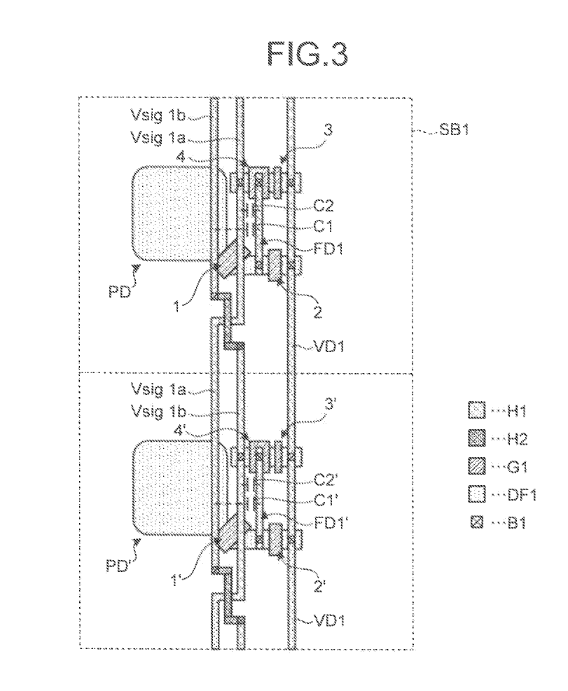

FIG. 3 is a plane view illustrating a layout configuration of the two pixels being mutually adjacent in the column direction of FIG. 1.

As illustrated in FIG. 3, at the two pixels PX being mutually adjacent in the column direction, the photodiodes PD1, PD1′ are structured by forming a diffusion layer DF1 on a semiconductor substrate SB1. Further, gate electrodes G1 are arranged respectively on the semiconductor substrate SB1. The read transistors 1, 1′, the reset transistors 2, 2′, the address transistors 3, 3′ and the amplifier transistors 4, 4′ are structured by forming the diffusion layer DF1 respectively at both sides of the gate electrodes G1. Further, the floating diffusion FD1 is structured by connecting the diffusion layer DF1 between the gate electrode G1 of the read transistor 1 and the gate electrode G1 of the reset transistor 2 to the gate electrode G1 of the amplifier transistor 4 through a via hole B1 and a wire H1. Further, the floating diffusion FD1′ is structured by connecting the diffusion layer DF1 between the gate electrode G1 of the read transistor 1′ and the gate electrode G1 of the reset transistor 2′ to the gate electrode G1 of the amplifier transistor 4′ through a via hole B1 and a wire H1.

Further, the vertical signal lines Vsig1a, Vsig1b are constituted with two wires H1 arranged being mutually adjacent. At the intersecting position of the vertical signal lines Vsig1a, Vsig1b, one of the two wires H1 remains connected while the other is disconnected. The discontinued position is connected with a wire H2 through the via hole B1. Here, the wires H1, H2 can be arranged respectively at different wiring layers. For example, the wire H1 can be arranged at a wiring layer of the first layer and the wire H2 can be arranged at a wiring layer of the second layer. Further, disconnection at the intersecting position of the wires H1 used for the vertical signal lines Vsig1a, Vsig1b can be performed alternately against the vertical signal lines Vsig1a, Vsig1b. Further, the vertical signal lines Vsig1a, Vsig1b may mutually change places vertically at the intersection position thereof.

Here, it is preferable that positions of the wires H1 in the row direction after the intersecting of the vertical signal lines Vsig1a, Vsig1b are to be aligned. The vertical signal line Vsig1a is preferably arranged to be in alignment with the vertical signal line Vsig1b between the pixels PX being mutually adjacent. Further, the power source line VD1 is constituted with a wire H1 arranged as being adjacent to the vertical signal lines Vsig1a, Vsig1b.

The wire H1 utilized for the vertical signal line Vsig1a is connected to the diffusion layer DF1 of the source side of the amplifier transistor 4 through the via hole B1. The wire H1 utilized for the vertical signal line Vsig1b is connected to the diffusion layer DF1 of the source side of the amplifier transistor 4′ through the via hole B1. Further, the wire H1 utilized for the power source line VD1 is connected to the diffusion layer DF1 of the drain side of the reset transistors 2, 2′ through the via hole B1.

Here, even in the case that two pixels PX being mutually adjacent in the column direction are respectively connected to different vertical signal lines Vsig1a, Vsig1b, the two pixels PX can be laid out as being completely aligned by arranging the vertical signal lines Vsig1a, Vsig1b as mutually intersecting for every pixel on the column direction. Accordingly, pixel characteristics and optical characteristics can be evened.

Further, by connecting the wires H1 utilized for the vertical signal lines Vsig1a, Vsig1b respectively to the diffusion layer DF1 of the source side of the amplifier transistors 4, 4′, distance between the floating diffusion FD1, FD1′ and the vertical signal lines Vsig1b, Vsig1a can be respectively enlarged. Therefore, the parasitic capacitances C1, C1′ between the vertical signal lines Vsig1a, Vsig1b transmitting a pixel signal of another pixel PX and the floating diffusions FD1, FD1′ of the own pixel PX can be lessened. Even in the case that the vertical signal lines Vsig1a, Vsig1b transmitting a pixel signal of another pixel PX are arranged at the own pixel PX, crosstalk caused by capacitance coupling of the parasitic capacitances C1, C1′ can be reduced.

By completely aligning layout of pixels PX being mutually adjacent in the column direction, the parasitic capacitances C2, C2′ between the vertical signal lines Vsig1a, Vsig1b transmitting the pixel signal of the own pixel and the floating diffusions FD1, FD1′ of the own pixel PX can be mutually the same. Accordingly, conversion gains of pixels PX being mutually adjacent in the column direction can be evened.

In the abovementioned first embodiment, the method to arrange two lines out of the vertical signal lines Vsig1a to Vsig1a and Vsig1b to Vsig1b for each column is described. However, the vertical signal lines to be arranged for each column are not limited to two lines. It is also possible that n lines (n is integer of 2 or larger) of the vertical signal lines are arranged for each column. In this case, it is possible that pixels PX of each column are divided into n groups and the pixels are connected to different vertical signal lines for each group. For example, n pieces of pixels being mutually adjacent in the column direction can be connected to mutually different vertical signal lines of each column. Further, one of the vertical signal lines of each column can intersect n−1 lines of the vertical signal lines of the same column for each pixel.

Further, each vertical signal line can repeatedly appear in the column direction for every n−1 pieces of pixels of the same column. In other words, arrangement order of n−1 lines of vertical signal lines is repeated for every n pieces of pixels of the same column. For example, it is possible that each of n lines of vertical signal lines arranged in parallel at the each column is shifted to the position of the next vertical signal line as proceeding by one pixel and that the vertical signal line at the right end is located to be the left end.

Further, each pixel PX of each column can be connected to the same vertical signal line for every n pieces of pixels PX in the column direction. Further, pixel signals can be simultaneously read out to n lines of vertical signal lines of each column from n pieces of pixels PX belonging to mutually different groups. Furthermore, it is possible that each of n lines of the vertical signal lines on the same column intersects other n−1 lines of the vertical signal lines thereover n−1 times by one line every time after once intersecting other n−1 lines of the vertical signal lines thereunder.

### Second Embodiment

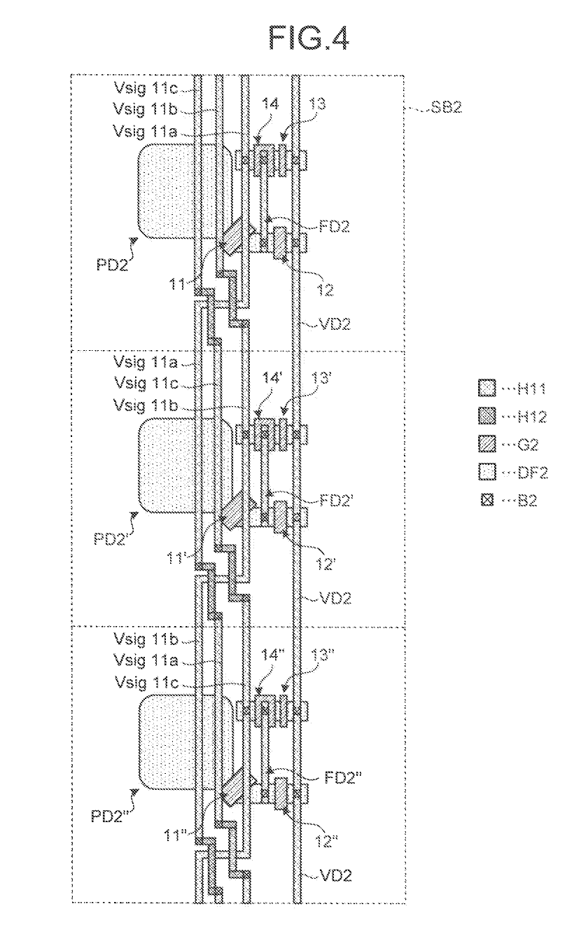

FIG. 4 is a plane view illustrating a layout configuration of mutually adjacent three pixels of a solid-state imaging apparatus according to the second embodiment of the invention.

In the three pixels PX being mutually adjacent in the column direction, photodiodes PD2, PD2′, PD2″ are structured by forming a diffusion layer DF2 on a semiconductor substrate SB2. Further, gate electrodes G2 are arranged respectively on the semiconductor substrate SB2. Read transistors 11, 11′, 11″, reset transistors 12, 12′, 12″, address transistors 13, 13′, 13″ and amplifier transistors 14, 14′, 14″ are structured by forming the diffusion layer DF2 respectively at both sides of the gate electrodes G2. Further, the floating diffusion FD2 is structured by connecting the diffusion layer DF2 between the gate electrode G2 of the read transistor 11 and the gate electrode G2 of the reset transistor 12 to the gate electrode G2 of the amplifier transistor 14 through a via hole B2 and a wire H11. Further, the floating diffusion FD2′ is structured by connecting the diffusion layer DF2 between the gate electrode G2 of the read transistor 11′ and the gate electrode G2 of the reset transistor 12′ to the gate electrode G2 of the amplifier transistor 14′ through a via hole B2 and a wire H11. Further, the floating diffusion FD2″ is structured by connecting the diffusion layer DF2 between the gate electrode G2 of the read transistor 11″ and the gate electrode G2 of the reset transistor 12″ to the gate electrode G2 of the amplifier transistor 14″ through a via hole B2 and a wire H11.

Further, the vertical signal lines Vsig11a, Vsig11b, Vsig11c are constituted with three wires H11 arranged being mutually adjacent. At intersecting positions of the vertical signal lines Vsig11a, Vsig11b, Vsig11c, one of the three wires H11 remains connected while the remaining two wires H11 are disconnected. The discontinued positions are respectively connected with a wire H12 through the via hole B2. Here, the wires H11, H12 can be arranged respectively at different wiring layers. For example, the wire H11 can be arranged at a wiring layer of the first layer and the wire H12 can be arranged at a wiring layer of the second layer. Further, disconnection at the intersecting positions of the wires H11 used for the vertical signal lines Vsig11a, Vsig11b, Vsig11c can be performed sequentially against the vertical signal lines Vsig11a, Vsig11b, Vsig11c.

Here, it is preferable that positions of the wires H11 in the row direction after the intersecting of the vertical signal lines Vsig11a, Vsig11b, Vsig11c are to be aligned. The vertical signal line Vsig11a is preferably arranged to be in alignment with the vertical signal lines Vsig11b, Vsig11c among three pixels PX being mutually adjacent. Further, the power source line VD2 is constituted with a wire H11 arranged as being adjacent to the vertical signal lines Vsig11a, Vsig11b, Vsig11c.

The wire H11 utilized for the vertical signal line Vsig11a is connected to the diffusion layer DF2 of the source side of the amplifier transistor 14 through the via hole B2. The wire H11 utilized for the vertical signal line Vsig11b is connected to the diffusion layer DF2 of the source side of the amplifier transistor 14′ through the via hole B2. The wire H11 utilized for the vertical signal line Vsig11c is connected to the diffusion layer DF2 of the source side of the amplifier transistor 14″ through the via hole B2. Further, the wire H11 utilized for the power source line VD2 is connected to the diffusion layer DF2 of the drain side of the reset transistors 12, 12′, 12″ through the via hole B2.

Here, even in the case that three pixels PX being mutually adjacent in the column direction are respectively connected to different vertical signal lines Vsig11a, Vsig11b, Vsig11c, the three pixels PX can be laid out as being completely aligned by arranging the vertical signal lines Vsig11a, Vsig11b, Vsig11c as mutually intersecting for every pixel on the column direction. Accordingly, pixel characteristics and optical characteristics can be evened.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging apparatus comprising:
pixels arrayed in a matrix shape in the row direction and the column direction;
horizontal control lines which selects the pixels in the row direction;
vertical signal lines which have n lines (n is integer of 2 or larger) thereof arranged for each column as mutually intersecting and which are connected separately to pixels divided into n groups for each column; and
a vertical scan circuit which selects the horizontal control lines.

2. The solid-state imaging apparatus according to claim 1,
wherein n pieces of pixels being mutually adjacent in the column direction are connected to mutually different vertical signal lines of each column.

3. The solid-state imaging apparatus according to claim 2, wherein one of vertical signal lines of each column intersects n−1 lines of the vertical signal lines of the same column for every pixel.

4. The solid-state imaging apparatus according to claim 3, wherein pixels of each column are connected to the same vertical signal line for every n−1 pieces in the column direction.

5. The solid-state imaging apparatus according to claim 1, further comprising a signal processing circuit which processes a pixel signal read out via the vertical signal line;
wherein the vertical scan circuit selects the horizontal control lines so that pixel signals are simultaneously read out to n lines of vertical signal lines of each column from n pieces of pixels belonging to mutually different groups; and
the signal processing circuit simultaneously processes the pixel signals read out from the n pieces of pixels respectively via the n lines of vertical signal lines.

6. The solid-state imaging apparatus according to claim 1, wherein the pixel signals of each column is read out to the nearest vertical signal line among n lines of vertical signal lines of each column.

7. The solid-state imaging apparatus according to claim 6, wherein the pixel includes a photodiode to perform photoelectric conversion, an address transistor to perform row selection, a reset transistor to reset a signal accumulated at the floating diffusion, a read transistor to read out a signal from the photodiode to the floating diffusion, and an amplifier transistor to amplify a signal read out from the photodiode to the floating diffusion.

8. The solid-state imaging apparatus according to claim 7, wherein layouts of the pixels being mutually adjacent in the column direction are mutually the same.

9. The solid-state imaging apparatus according to claim 8, wherein the vertical signal line repeatedly appears in the column direction for every n−1 pieces of pixels of the same column.

10. The solid-state imaging apparatus according to claim 9, further comprising a power source line arranged being adjacent to the vertical signal line for each column.

11. The solid-state imaging apparatus according to claim 9, wherein the pixels are arrayed so as to be aligned in position in the column direction for each column.

12. The solid-state imaging apparatus according to claim 11, wherein each of n lines of vertical signal lines on the same column intersects other n−1 lines of the vertical signal lines thereover n−1 times by one line every time after once intersecting other n−1 lines of the vertical signal lines thereunder.

13. The solid-state imaging apparatus according to claim 12, wherein the vertical signal lines are formed by utilizing wiring of two layers.

14. A solid-state imaging apparatus comprising:
pixels arrayed in a matrix shape in the row direction and the column direction;
horizontal control lines which selects the pixels in the row direction;
a first vertical signal line which transmits signals read out from even-numbered pixels of the column direction;
a second vertical signal line which is arranged so as to intersect the first vertical signal line and which transmits signals read out from odd-numbered pixels of the column direction; and
a vertical scan circuit which selects the horizontal control lines.

15. The solid-state imaging apparatus according to claim 14, wherein the second vertical signal line intersects the first vertical signal line for each pixel.

16. The solid-state imaging apparatus according to claim 14, further comprising a signal processing circuit which processes a first pixel signal transmitted via the first vertical signal line and a second pixel signal transmitted via the second vertical signal line;
wherein the vertical scan circuit selects the horizontal control lines so that the first pixel signal and the second pixel signal are simultaneously read out respectively from even-numbered pixels and odd-numbered pixels in the column direction, and
the signal processing circuit simultaneously processes the first pixel signal and the second pixel signal.

17. The solid-state imaging apparatus according to claim 16, wherein the pixel includes a photodiode to perform photoelectric conversion, an address transistor to perform row selection, a reset transistor to reset a signal accumulated at the floating diffusion, a read transistor to read out a signal from the photodiode to the floating diffusion, and an amplifier transistor to amplify a signal read out from the photodiode to the floating diffusion.

18. The solid-state imaging apparatus according to claim 17, wherein layouts of the pixels being mutually adjacent in the column direction are mutually the same.

19. The solid-state imaging apparatus according to claim 18, wherein the first vertical signal line and the second vertical signal line repeatedly appear alternately in the column direction for every one pixel of the same column.

20. The solid-state imaging apparatus according to claim 19, wherein the first vertical signal line and the second vertical signal line mutually change places vertically at an intersection position thereof.
